(19) United States
(12) Patent Application Publication
(10) Pub. No.: US 2021/0313964 A1
(43) Pub. Date: Oct. 7, 2021

(54) ACOUSTIC RESONATOR FILTER

(71) Applicant: Samsung Electro-Mechanics Co., Ltd., Suwon-si (KR)

(72) Inventors: Jung Woo SUNG, Suwon-si (KR); June Kyoo LEE, Suwon-si (KR)

(73) Assignee: Samsung Electro-Mechanics Co., Ltd., Suwon-si (KR)

(21) Appl. No.: 16/910,564

(22) Filed: Jun. 24, 2020

(30) Foreign Application Priority Data
Apr. 1, 2020 (KR) 10-2020-0039668

(51) Int. Cl. H03H 9/58; H03H 9/17; H03H 9/54; H03H 9/60

(52) U.S. Cl. CPC H03H 9/582; H03H 9/605; H03H 9/542; H03H 9/171

(57) ABSTRACT

An acoustic resonator filter includes at least one series acoustic resonator, electrically connected between a first port and a second port through which a radio frequency (RF) signal passes, a branch node electrically connected to the at least one series acoustic resonator and having a respective first shunt connection path and a second shunt connection path each extended toward a ground, a first shunt acoustic resonator electrically connected in series with the first shunt connection path, and a second shunt acoustic resonator electrically connected in series with the second shunt connection path, and having a resonance frequency higher than a resonance frequency of the first shunt acoustic resonator. An inductance of the second shunt connection path is higher than an inductance of the first shunt connection path.

### CROSS-REFERENCE TO RELATED APPLICATIONS

This application claims the benefit under 35 USC 119(a) of Korean Patent Application No. 10-2020-0039668, filed on Apr. 1, 2020 in the Korean Intellectual Property Office, the entire disclosure of which is incorporated herein by reference for all purposes.

### BACKGROUND

### 1. Field

The following description relates to an acoustic resonator filter.

### 2. Description of Related Art

With the recent rapid development of mobile communication devices, chemical devices, and biological devices, the demand for small and lightweight filters, oscillators, resonant elements and acoustic resonant mass sensors implemented in such devices is increasing.

An acoustic resonator may be configured as a device that implements such a small and lightweight filter, an oscillator, a resonator element, an acoustic resonant mass sensor, etc., and may be implemented as a thin film bulk acoustic resonator (FBAR).

FBAR may be mass-produced at minimal cost, and is advantageous in that it may be implemented in a very small size. Additionally, with FBAR, high quality factor (Q) values, which are the main characteristics of filters, may be implemented, and may be used in the micro-frequency band, and specifically, in Personal Communication System (PCS) and Digital Cordless System (DCS) bands.

The acoustic resonator filter may have frequency characteristics that are based on a combined structure of a plurality of acoustic resonators, and may have an excellent skirt characteristic pass bandwidth, and thus is widely used in electronic devices equipped with communication means, which may need a wide pass bandwidth to increase the data transmission/reception rate and communication speed.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In a general aspect, an acoustic resonator includes at least one series acoustic resonator, electrically connected between a first port and a second port through which a radio frequency (RF) signal passes, a branch node electrically connected to the at least one series acoustic resonator, and having a respective first shunt connection path and a second shunt connection path each extended toward a ground, a first shunt acoustic resonator, electrically connected in series with the first shunt connection path; and a second shunt acoustic resonator, electrically connected in series with the second shunt connection path, and having a resonance frequency higher than a resonance frequency of the first shunt acoustic resonator, wherein an inductance of the second shunt connection path is higher than an inductance of the first shunt connection path.

The acoustic resonator filter may include an inductor electrically connected in series with the second shunt connection path.

An inductance of the inductor may be greater than 1 nH and less than 10 nH.

The inductance of the first shunt connection path may be less than 1 nH.

The resonant frequency of the first shunt acoustic resonator and the resonant frequency of the second shunt acoustic resonator may each be greater than 2.3 GHz and less than 2.9 GHz.

A value of the resonant frequency of the second shunt acoustic resonator may be closer to a value of a resonant frequency of the at least one series acoustic resonator than a value of the resonant frequency of the first shunt acoustic resonator.

The resonant frequency of the second shunt acoustic resonator may be higher than an antiresonant frequency of the first shunt acoustic resonator.

The at least one series acoustic resonator may include a first series acoustic resonator, electrically connected between the branch node and the first port; and a second series acoustic resonator, electrically connected between the branch node and the second port.

The branch node may be configured to prevent self-resonance between the first series acoustic resonator and the second series acoustic resonator.

The acoustic resonator filter may include a second branch node electrically connected between the first series acoustic resonator and the first port, and having a third shunt connection path toward the ground; and a third shunt acoustic resonator electrically connected in series with the third shunt connection path, and having a resonance frequency lower than the resonance frequency of the second shunt acoustic resonator, wherein an inductance of the second shunt connection path is greater than an inductance of the third shunt connection path.

The acoustic resonator filter may include a third branch node electrically connected between the second series acoustic resonator and the second port and having a fourth shunt connection path toward the ground; and a fourth shunt acoustic resonator electrically connected in series with the fourth shunt connection path, and having a resonance frequency less than the resonance frequency of the second shunt acoustic resonator, wherein an inductance of the second shunt connection path is greater than an inductance of the fourth shunt connection path.

The at least one series acoustic resonator further may include a third series acoustic resonator, electrically connected between the second branch node and the first port, and the acoustic resonator filter may further include a first impedance matching circuit electrically connected between the third series acoustic resonator and the first port, and a second impedance matching circuit electrically connected between the second series acoustic resonator and the second port.

Each of the first shunt acoustic resonator and the second shunt acoustic resonator may be a film bulk acoustic resonator.

In a general aspect, an acoustic resonator filter includes at least one series acoustic resonator connected between a first port and a second port, a first shunt connection path connected between the first port and the second port, a second shunt connection path connected between the first port and the second port, and having an inductance higher than an inductance of the first shunt connection path, a first film bulk acoustic resonator (FBAR) connected in series with the first shunt connection path; and a second FBAR connected in series with the second shunt connection path, and having a resonance frequency higher than a resonance frequency of the first FBAR.

The acoustic resonator filter may include an inductor electrically connected in series with the second FBAR.

Other features and aspects will be apparent from the following detailed description, the drawings, and the claims.

### BRIEF DESCRIPTION OF DRAWINGS

FIG. 1 illustrates an example acoustic resonator filter, in accordance with one or more embodiments.

FIG. 2 is a graph illustrating S-parameters of an example acoustic resonator filter, in accordance with one or more embodiments.

FIGS. 3A to 3C illustrate a modified example acoustic resonator filter, in accordance with one or more embodiments.

FIG. 4 illustrates a simplified example acoustic resonator filter, in accordance with one or more embodiments.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known, after an understanding of the disclosure of the application, may be omitted for increased clarity and conciseness.

The features described herein may be embodied in different forms, and are not to be construed as being limited to the examples described herein. Rather, the examples described herein have been provided so that this disclosure will be thorough and complete, and will fully convey the scope of the disclosure to one of ordinary skill in the art.

Herein, it is noted that use of the term “may” with respect to an example or embodiment, e.g., as to what an example or embodiment may include or implement, means that at least one example or embodiment exists in which such a feature is included or implemented while all examples and embodiments are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there may be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes illustrated in the drawings may occur. Thus, the examples described herein are not limited to the specific shapes illustrated in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

Unless otherwise defined, all terms, including technical and scientific terms, used herein have the same meaning as commonly understood by one of ordinary skill in the art to which this disclosure pertains after an understanding of the disclosure of this application. Terms, such as those defined in commonly used dictionaries, are to be interpreted as having a meaning that is consistent with their meaning in the context of the relevant art and the disclosure of the present application, and are not to be interpreted in an idealized or overly formal sense unless expressly so defined herein.

The drawings may not be to scale, and the relative size, proportions, and depiction of elements in the drawings may be exaggerated for clarity, illustration, and convenience.

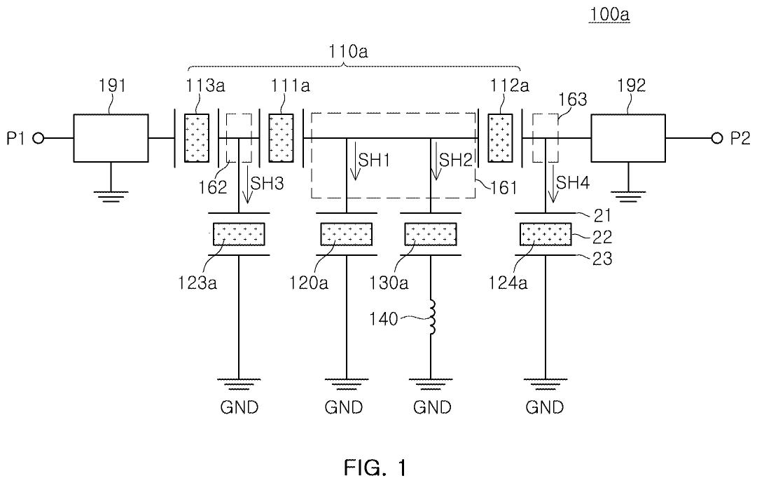

FIG. 1 illustrates an example acoustic resonator filter, in accordance with one or more embodiments.

Referring to FIG. 1, an acoustic resonator filter 100a according to an example may include at least one series acoustic resonator 110a, a branch node 161, a first shunt acoustic resonator 120a, and a second shunt acoustic resonator 130a, and may pass or block a radio frequency (RF) signal between a first port P1 and a second port P2 based on the frequency of the RF signal.

The at least one series acoustic resonator 110a, the first shunt acoustic resonator 120a, and the second shunt acoustic resonator 130a may each include a piezoelectric layer 22 and a plurality of electrodes 21 and 23 disposed on both sides of the piezoelectric layer 22, and may have piezoelectric properties.

The piezoelectric layer 22 may include a piezoelectric material that generates a piezoelectric effect that converts electrical energy into mechanical energy in the form of elastic waves. For example, the piezoelectric material may include, as non-limiting examples, one of aluminum nitride (AlN), zinc oxide (ZnO), and lead zirconium titanium oxide (PZT; PbZrTiO), and may further include, as non-limiting examples, at least one of rare earth metal and a transition metal, and may also include, as non-limiting examples, magnesium (Mg) which is a divalent metal. For example, the rare earth metal may include, as non-limiting examples, at least one of scandium (Sc), erbium (Er), yttrium (Y), and lanthanum (La), and the transition metal may include, as non-limiting examples, at least one of titanium (Ti), zirconium (Zr), hafnium (Hf), tantalum (Ta), and niobium (Nb).

In an example, the plurality of electrodes 21 and 23 may be formed with a conductive material such as, for example, molybdenum (Mo) or an alloy thereof to improve the bonding efficiency with the piezoelectric layer 22, but the material thereof is not limited thereto. For example, the plurality of electrodes 21 and 23 are formed of a conductive material such as ruthenium (Ru), tungsten (W), iridium (Ir), platinum (Pt), copper (Cu), titanium (Ti), tantalum (Ta), nickel (Ni), chromium (Cr), etc. or alloys thereof.

The at least one series acoustic resonator 110a, the first shunt acoustic resonator 120a, and the second shunt acoustic resonator 130a may respectively convert electrical energy of the RF signal into mechanical energy and may perform reverse-conversion through piezoelectric characteristics. The closer the signal frequency is to the resonance frequency of the acoustic resonator, the higher the energy transfer rate between the plurality of electrodes may be. The closer the frequency of the RF signal is to the antiresonance frequency of the acoustic resonator, the energy transfer rate between the plurality of electrodes may be greatly reduced. On the basis of the piezoelectric characteristics, the antiresonance frequency may be higher than the resonance frequency.

The at least one series acoustic resonator 110a may be electrically connected between the first and second ports P1 and P2. The closer the frequency of the RF signal is to the resonance frequency, the pass rate of the RF signal between the first and second ports P1 and P2 may increase, and the closer the frequency of the RF signal is to the antiresonance frequency, the lower the pass rate of the RF signal between the first and second ports P1 and P2 may be.

The branch node 161 may be electrically connected to at least one series acoustic resonator 110a, and may have first and second shunt connection paths SH1 and SH2 toward the ground GND. In an example, the branch node 161 may be implemented using, as non-limiting examples, a material such as gold (Au), a gold-tin (Au—Sn) alloy, copper (Cu), a copper-tin (Cu—Sn) alloy, and aluminum (Al), an aluminum alloy or the like.

The first shunt acoustic resonator 120a may be electrically connected in series with the first shunt connection path SH1, and the closer the frequency of the RF signal is to the resonance frequency, the pass rate of the RF signal between the branch node 161 and the ground (GND) may be increased. Additionally, as the frequency of the RF signal approaches the antiresonance frequency, the pass rate of the RF signal between the branch node 161 and the ground (GND) may be lowered.

The pass rate of the RF signal between the first and second ports P1 and P2 may be lowered as the pass rate of the RF signal between the branch node 161 and the ground (GND) increases, and may be increased as the pass rate of the RF signal between the branch node 161 and the ground (GND) decreases.

In an example, the pass rate of the RF signal between the first and second ports P1 and P2 may be higher as the frequency approaches the resonant frequency of the first shunt acoustic resonator 120a, or the antiresonant frequency of the at least one series acoustic resonator 110a.

Since the antiresonant frequency is higher than the resonant frequency, the acoustic resonator filter 100a may have a pass bandwidth that is formed at a lowest frequency corresponding to the resonant frequency of the first shunt acoustic resonator 120a and at a highest frequency corresponding to the antiresonant frequency of at least one series acoustic resonator 110a.

The pass bandwidth may be widened as the difference between the resonant frequency of the first shunt acoustic resonator 120a and at the highest frequency the antiresonant frequency of the at least one series acoustic resonator 110a is increased. However, if the difference is too great, the pass bandwidth may be split.

When the resonant frequency of the at least one series acoustic resonator 110a is slightly higher than the antiresonant frequency of the first shunt acoustic resonator 120a, the bandwidth of the acoustic resonator filter 100a may not be split while being relatively wide.

The difference between the resonant frequency and the antiresonant frequency in the acoustic resonator may be determined based on the physical characteristic, kt² (electromechanical coupling factor), of the acoustic resonator, and when the size or shape of the acoustic resonator is changed, the resonant frequency and the antiresonant frequency may be changed together therewith.

The second shunt acoustic resonator 130a may be electrically connected in series with the second shunt connection path SH2, and may have a resonance frequency that is higher than a resonance frequency of the first shunt acoustic resonator 120a. The antiresonant frequency of the second shunt acoustic resonator 130a may also be higher than the antiresonant frequency of the first shunt acoustic resonator 120a.

In an example, the inductance of the second shunt connection path SH2 may be greater than the inductance of the first shunt connection path SH1.

In an example, the acoustic resonator filter 100a according to an example may further include an inductor 140 electrically connected in series with the second shunt connection path SH2, to further increase the inductance of the second resonator connection path SH2.

The additional inductance of the shunt connection path may contribute to the resonance frequency of the shunt connection path. On the other hand, the additional inductance of the shunt connection path may not substantially contribute to the antiresonant frequency of the shunt connection path. For example, the characteristics of the shunt connection path having a relatively larger inductance may be similar to the characteristics of the shunt connection path of the acoustic resonator having a relatively larger kt².

Therefore, the difference between the resonant frequency and the antiresonant frequency of the shunt connection path may be increased as the inductance of the shunt connection path is increased.

Since the difference between the resonant frequency and the antiresonant frequency of the second shunt connection path SH2 is relatively greater, and the resonance frequency of the second shunt acoustic resonator 130a is higher than the resonance frequency of the first shunt acoustic resonator 120a; the resonant frequency and antiresonant frequency of the second shunt connection path SH2 may compensate for a split of the pass bandwidth caused as the difference between the resonant frequency of the first shunt acoustic resonator 120a and the antiresonant frequency of the at least one series acoustic resonator 110a is excessively increased.

Therefore, the pass bandwidth of the acoustic resonator filter 100a according to an example may be further widened.

Additionally, when the inductor 140 is added to the second shunt connection path SH2, the impedance characteristic of the second shunt connection path SH2 may ensure the resonance frequency of the second shunt connection path SH2 to more effectively move to a relatively low frequency band.

Accordingly, the acoustic resonator filter 100a according to an example may use the inductor 140 to increase the inductance of the second shunt connection path SH2, thereby more efficiently increasing the difference between the resonance frequency and the antiresonance frequency of the second shunt connection path SH2 and more efficiently widening the pass bandwidth between the first and second ports P1 and P2.

In an example, the inductance of the inductor 140 may be greater than 1 nH and less than 10 nH.

Accordingly, since the impedance characteristic of the second shunt connection path SH2 may more effectively lower the resonance frequency of the second shunt connection path SH2, the pass bandwidth between the first and second ports P1 and P2 may be further broadened efficiently.

For example, the resonance frequency of the first shunt acoustic resonator 120a and the resonance frequency of the second shunt acoustic resonator 130a may be each higher than 2.3 GHz and lower than 2.9 GHz. For example, the first and second shunt acoustic resonators 120a and 130a may be efficiently implemented as a film bulk acoustic resonator (FBAR) to have an efficient resonant frequency higher than 2.3 GHz and lower than 2.9 GHz.

In an example, the inductance of the first shunt connection path SH1 may be less than 1 nH. Accordingly, the difference in inductance between the first and second shunt connection paths SH1 and SH2 may be further increased, and the acoustic resonator filter 100a according to an example may more effectively widen the pass bandwidth.

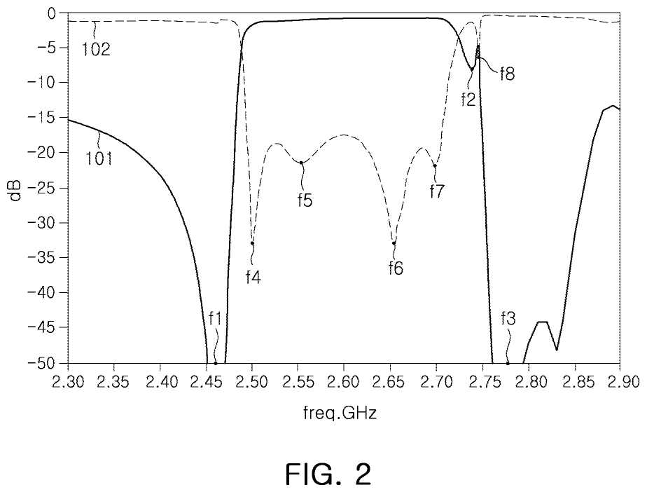

FIG. 2 is a graph illustrating S-parameters of an acoustic resonator filter, in accordance with one or more embodiments.

Referring to FIG. 2, an S-parameter 101 between the first port and the second port may have a relatively low value at a first frequency f1, a second frequency f2, and a third frequency f3. An S-parameter 102 between the first port and the first port may have a relatively low value at a fourth frequency f4, a fifth frequency f5, a sixth frequency f6, a seventh frequency f7 and an eighth frequency f8.

The S-parameter 101 between the first port and the second port may indicate the pass characteristic of the RF signal, and may have a pass bandwidth including a band of 2496 to 2690 MHz. An RF signal having a frequency within the pass bandwidth may pass between the first and second ports, and an RF signal having a frequency deviating from the pass bandwidth may not pass between the first and second ports.

The first frequency f1 may correspond to the resonant frequency of the first shunt connection path, and the third frequency f3 may correspond to the antiresonant frequency of at least one series acoustic resonator.

The S-parameter 102 between the first port and the second port may represents the reflection characteristic of the RF signal, and the reflectivity of the RF signal may be low at the fourth and fifth frequencies f4 and f5 relatively close to the resonance frequency of the first shunt connection path, and may be low at the sixth and seventh frequencies f6 and f7 relatively close to the resonance frequency of the second shunt connection path.

In an example, the resonance frequency of the second shunt acoustic resonator may be configured to be closer to the resonance frequency of the at least one series acoustic resonator than the resonance frequency of the first shunt acoustic resonator.

Accordingly, the S-parameter 101 between the first port and the second port in the pass bandwidth may have a stable value, and the acoustic resonator filter according to an example may stabilize the pass bandwidth, for example, may reduce a ripple magnitude.

For example, the resonant frequency of the second shunt acoustic resonator may be higher than the antiresonant frequency of the first shunt acoustic resonator. For example, the resonance frequency of the second shunt acoustic resonator may be substantially the same as the resonance frequency of at least one series acoustic resonator.

Accordingly, the acoustic resonator filter according to an example may form a more optimized pass bandwidth.

On the other hand, a value corresponding to a frequency that greatly deviates from a pass bandwidth in the S-parameter 102 between the first port and the second port may be determined by the influence of other frequency selection structures, such as first and/or second impedance matching circuits.

Referring again to FIG. 1, the at least one series acoustic resonator 110a may include a first series acoustic resonator 111a electrically connected between the branch node 161 and the first port P1, and a second series acoustic resonator 112a electrically connected between and the branch node 161 and the second port P2, and may further include a third series acoustic resonator 113a.

Skirt characteristics in the vicinity of a highest frequency of the pass bandwidth of the acoustic resonator filter 100a may be further improved as the number of series acoustic resonators increases.

Insertion loss of the acoustic resonator filter 100a may increase as the number of series acoustic resonators of the at least one series acoustic resonator 110a increases.

The branch node 161 may be configured not to cause self-resonance between the first series acoustic resonator 111a and the second series acoustic resonator 112a. In an example, an acoustic resonator may not be provided between the first series acoustic resonator 111a and the second series acoustic resonator 112a.

Due to the difference in frequency characteristics of the first and second shunt connection paths SH1 and SH2, even though the branch node 161 includes an acoustic resonator for generating self-resonance and increasing insertion loss, the self-resonance of the branch node 161 may hardly influence the skirt characteristics of the acoustic resonator filter 100a, compared to the first and second series acoustic resonators 111a and 112a.

Therefore, the acoustic resonator filter 100a according to an example may be configured to not cause self-resonance between the first series acoustic resonator 111a and the second series acoustic resonator 112a, thereby reducing insertion loss while ensuring skirt characteristics.

Referring to FIG. 1, the acoustic resonator filter 100a according to an example may further include at least one of a third shunt acoustic resonator 123a, a fourth shunt acoustic resonator 124a, a second branch node 162, and a third branch node 163, a first impedance matching circuit 191, and a second impedance matching circuit 192.

The second branch node 162 may be electrically connected between the first series acoustic resonator 111a and the first port P1, and may have a third shunt connection path SH3 toward the ground GND.

The third shunt acoustic resonator 123a may be electrically connected in series with the third shunt connection path SH3, and may have a resonance frequency lower than a resonance frequency of the second shunt acoustic resonator 130a. The inductance of the second shunt connection path SH2 may be greater than the inductance of the third shunt connection path SH3.

The skirt characteristics in the vicinity of the lowest frequency of the pass bandwidth of the acoustic resonator filter 100a may be further improved as the number of shunt acoustic resonators increases.

The third branch node 163 may be electrically connected between the second series acoustic resonator 112a and the second port P2, and may have a fourth shunt connection path SH4 toward the ground GND.

The fourth shunt acoustic resonator 124a may be electrically connected in series with the fourth shunt connection path SH4, and may have a resonance frequency that is lower than a resonance frequency of the second shunt acoustic resonator 130a. The inductance of the second shunt connection path SH2 may be greater than the inductance of the fourth shunt connection path SH4.

The first impedance matching circuit 191 may be electrically connected between the third series acoustic resonator 113a and the first port P1, and may block an RF signal having a frequency significantly out of the pass bandwidth of the acoustic resonator filter 100a.

The second impedance matching circuit 192 may be electrically connected between the second series acoustic resonator 112a and the second port P2, and may block an RF signal having a frequency that is significantly deviated from a pass bandwidth of the acoustic resonator filter 100a.

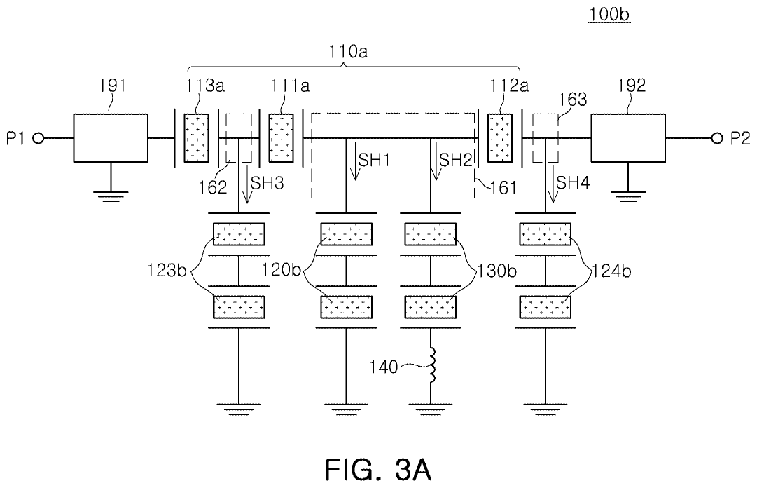

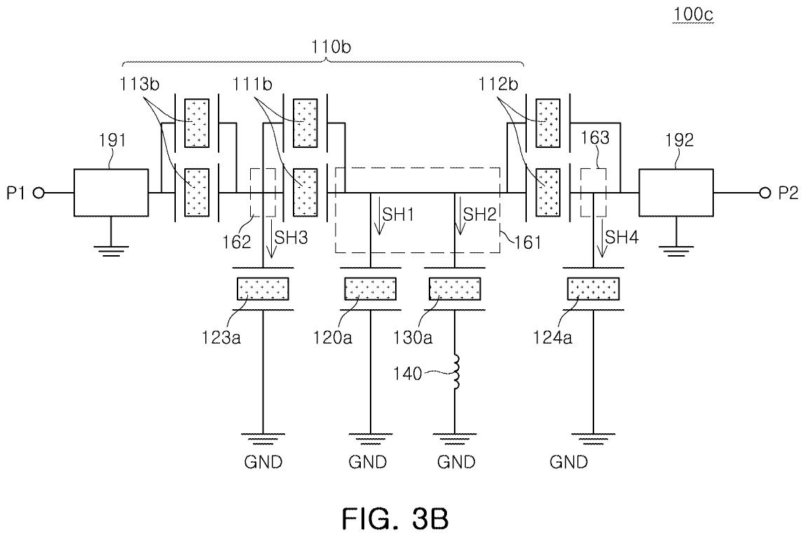

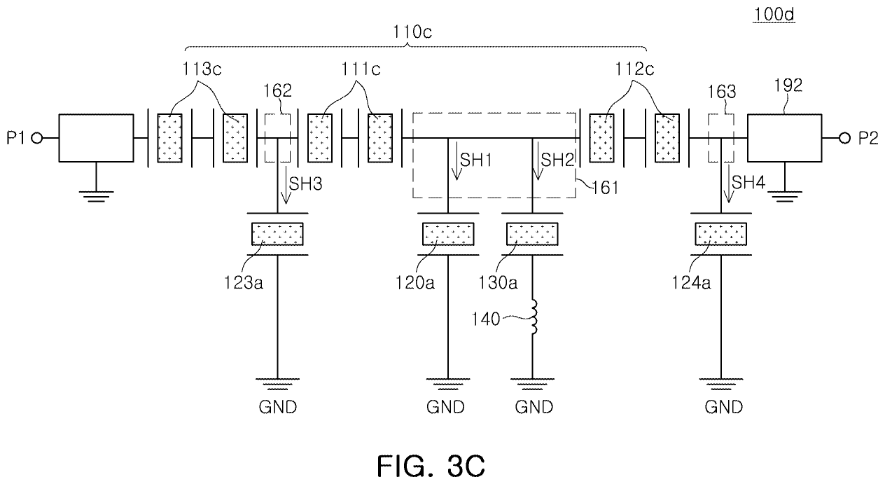

FIGS. 3A to 3C are diagrams illustrating a modified example acoustic resonator filter, in accordance with one or more embodiments.

Referring to FIG. 3A, an acoustic resonator filter 100b, according to an example, may include a plurality of first shunt acoustic resonators 120b, a plurality of second shunt acoustic resonators 130b, a plurality of third shunt acoustic resonators 123b, and a plurality of fourth shunt acoustic resonators 124b.

Referring to FIGS. 3B and 3C, an acoustic resonator filter 100c, according to an example, may include a plurality of series acoustic resonators 110b, and the plurality of series acoustic resonators 110b may include a plurality of first series acoustic resonator 111b, a plurality of second series acoustic resonators 112b, and a plurality of third series acoustic resonators 113b.

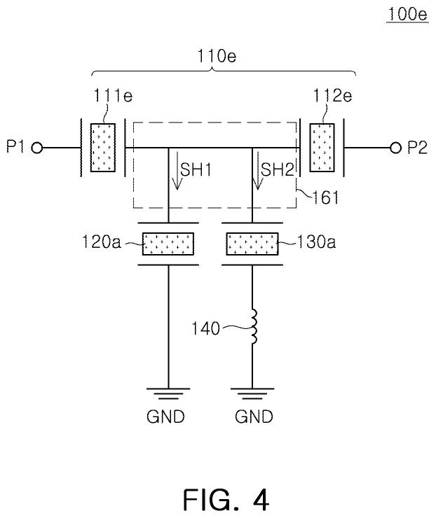

FIG. 4 illustrates a simplified example of an acoustic resonator filter, in accordance with one or more embodiments.

Referring to FIG. 4, an acoustic resonator filter 100e according to an example may have a structure in which the third series acoustic resonator, the third shunt acoustic resonator, and the fourth shunt acoustic resonator illustrated in FIG. 1 are omitted. The acoustic resonator filter 100e may have a relatively effective wider pass bandwidth.

As set forth above, according to examples, the acoustic resonator filter may have a relatively wider pass bandwidth effectively.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed to have a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An acoustic resonator filter comprising:
at least one series acoustic resonator, electrically connected between a first port and a second port through which a radio frequency (RF) signal passes;
a branch node electrically connected to the at least one series acoustic resonator, and having a respective first shunt connection path and a second shunt connection path each extended toward a ground;
a first shunt acoustic resonator, electrically connected in series with the first shunt connection path; and
a second shunt acoustic resonator, electrically connected in series with the second shunt connection path, and having a resonance frequency higher than a resonance frequency of the first shunt acoustic resonator,
wherein an inductance of the second shunt connection path is higher than an inductance of the first shunt connection path.

2. The acoustic resonator filter of claim 1, further comprising an inductor electrically connected in series with the second shunt connection path.

3. The acoustic resonator filter of claim 2, wherein an inductance of the inductor is greater than 1 nH and less than 10 nH.

4. The acoustic resonator filter of claim 3, wherein the inductance of the first shunt connection path is less than 1 nH.

5. The acoustic resonator filter of claim 3, wherein the resonant frequency of the first shunt acoustic resonator and the resonant frequency of the second shunt acoustic resonator are each greater than 2.3 GHz and less than 2.9 GHz.

6. The acoustic resonator filter of claim 1, wherein a value of the resonant frequency of the second shunt acoustic resonator is closer to a value of a resonant frequency of the at least one series acoustic resonator than a value of the resonant frequency of the first shunt acoustic resonator.

7. The acoustic resonator filter of claim 1, wherein the resonant frequency of the second shunt acoustic resonator is higher than an antiresonant frequency of the first shunt acoustic resonator.

8. The acoustic resonator filter of claim 1, wherein the at least one series acoustic resonator comprises:
a first series acoustic resonator, electrically connected between the branch node and the first port; and
a second series acoustic resonator, electrically connected between the branch node and the second port.

9. The acoustic resonator filter of claim 8, wherein the branch node is configured to prevent self-resonance between the first series acoustic resonator and the second series acoustic resonator.

10. The acoustic resonator filter of claim 8, further comprising:
a second branch node electrically connected between the first series acoustic resonator and the first port, and having a third shunt connection path toward the ground; and
a third shunt acoustic resonator electrically connected in series with the third shunt connection path, and having a resonance frequency lower than the resonance frequency of the second shunt acoustic resonator,
wherein an inductance of the second shunt connection path is greater than an inductance of the third shunt connection path.

11. The acoustic resonator filter of claim 10, further comprising:
a third branch node electrically connected between the second series acoustic resonator and the second port and having a fourth shunt connection path toward the ground; and
a fourth shunt acoustic resonator electrically connected in series with the fourth shunt connection path, and having a resonance frequency less than the resonance frequency of the second shunt acoustic resonator,
wherein an inductance of the second shunt connection path is greater than an inductance of the fourth shunt connection path.

12. The acoustic resonator filter of claim 11, wherein the at least one series acoustic resonator further comprises a third series acoustic resonator, electrically connected between the second branch node and the first port, and
the acoustic resonator filter further comprises:
a first impedance matching circuit electrically connected between the third series acoustic resonator and the first port, and
a second impedance matching circuit electrically connected between the second series acoustic resonator and the second port.

13. The acoustic resonator filter of claim 1, wherein each of the first shunt acoustic resonator and the second shunt acoustic resonator is a film bulk acoustic resonator.

14. An acoustic resonator filter comprising:
at least one series acoustic resonator connected between a first port and a second port;
a first shunt connection path connected between the first port and the second port;
a second shunt connection path connected between the first port and the second port, and having an inductance higher than an inductance of the first shunt connection path;
a first film bulk acoustic resonator (FBAR) connected in series with the first shunt connection path; and
a second FBAR connected in series with the second shunt connection path, and having a resonance frequency higher than a resonance frequency of the first FBAR.

15. The acoustic resonator filter of claim 14, further comprising an inductor electrically connected in series with the second FBAR.
